(19) United States
(12) Patent Application Publication
(10) Pub. No.: US 2026/0291506 A1
(43) Pub. Date: Sep. 24, 2026

(54) A WIDE-BAND, MULTI-PHASE PHASE-LOCKED LOOP CIRCUIT

(71) Applicant: University of Utah Research Foundation, Salt Lake City, UT (US)

(72) Inventors: Seyed Armin TAJALLI, Salt Lake City, UT (US); Rajath BINDIGANAVILE, Salt Lake City, UT (US); Asif WAHID, Salt Lake City, UT (US)

(21) Appl. No.: 18/874,421

(22) PCT Filed: Jun. 16, 2023
(86) PCT No.: PCT/US2023/068559

§ 371 Date: Dec. 12, 2024

Related U.S. Application Data
(60) Provisional application No. 63/353,453, filed on Jun. 17, 2022.

(51) Int. Cl. H03L 7/087; H03L 7/089

(52) U.S. Cl. CPC H03L 7/087; H03L 7/0891; H03L 2207/06

(57) ABSTRACT

A wide-band, multi-phase phase-locked loop (PLL) circuit (200) may include a voltage-controlled oscillator (VCO) (214). A divider circuit (222) coupled to the output of the VCO (214). A reconfigurable and programmable multi-phase phase frequency detector (PFD) and reconfigurable charge pump controller (CPC) circuit (PFD-CPC circuit) (210) may be coupled to the output of the divider circuit (222), where the PFD-CPC circuit (210) includes a multi-phase PFD and a plurality of identical slices of the reconfigurable CPC and is configured to operate in either single-phase or multi-phase mode to reduce phase noise and jitter contribution of one or more forward path loop components within a targeted frequency band.

### CROSS REFERENCE TO RELATED APPLICATIONS

The present application claims priority to U.S. Provisional Patent Application No. 63/353,453 filed Jun. 17, 2022, the entire specification of which is hereby incorporated by reference in its entirety for all purposes.

### STATEMENT REGARDING FEDERALLY SPONSORED RESEARCH OR DEVELOPMENT

This invention was made with government support under grant No. FA8650-19-2-7931 awarded by the Defense Advanced Research Projects Agency. The government has certain rights in the invention.

### NAMES OF THE PARTIES TO A JOINT RESEARCH AGREEMENT

Not applicable.

### INCORPORATION BY REFERENCE STATEMENT

Not applicable.

### BACKGROUND

In modern digital systems, digital information must be processed in a reliable and efficient way. In this context, digital information is to be understood as information available in discrete, i.e., discontinuous values. Bits, collection of bits, but also numbers from a finite set can be used to represent digital information.

In most chip-to-chip, or device-to-device communication systems, communication takes place over a plurality of wires to increase the aggregate bandwidth. A single or pair of these wires may be referred to as a channel or link and multiple channels create a communication bus between the electronic components. At the physical circuitry level, in chip-to-chip communication systems, buses are typically made of electrical conductors in the package between chips and motherboards, on printed circuit boards (PCBs) boards or in cables and connectors between PCBs. In high frequency applications, microstrip or stripline PCB traces may be used.

Common methods for transmitting signals over bus wires include single-ended and differential signaling methods. In applications requiring high speed communications, those methods can be further optimized in terms of power consumption and pin-efficiency, especially in high-speed communications. More recently, vector signaling methods have been proposed to further optimize the trade-offs between power consumption, pin efficiency and noise robustness of chip-to-chip communication systems. In such vector signaling systems, digital information at the transmitter is transformed into a different representation space in the form of a vector codeword that is chosen in order to optimize the power consumption, pin-efficiency and speed trade-offs based on the transmission channel properties and communication system design constraints. Herein, this process is referred to as “encoding”. The encoded codeword is communicated as a group of signals from the transmitter to one or more receivers. At a receiver, the received signals corresponding to the codeword are transformed back into the original digital information representation space. Herein, this process is referred to as “decoding”.

Regardless of the encoding method used, the received signals presented to the receiving device must be sampled (or their signal value otherwise recorded) at intervals best representing the original transmitted values, regardless of transmission channel delays, interference, and noise. Such Clock and Data Recovery (CDR) not only determines the appropriate sample timing, but may continue to do so continuously, providing dynamic compensation for varying signal propagation conditions. Many known CDR systems utilize a Phase-Locked Loop (PLL) or Delay-Locked Loop (DLL) to synthesize a local receive clock having an appropriate frequency and phase for accurate receive data sampling. The PPL is an electronic feedback control system used to generate a stable output signal that is synchronized in phase and frequency with an input reference signal. PPL are used in various electronic systems, such as communication systems, data converters, clock generation circuits, and frequency synthesizers. The basic operation of a PLL involves comparing the phase and frequency of the input reference signal (usually called the “reference” or “feedback” signal) with that of a generated output signal (called the “output” or “controlled” signal). The PLL uses a feedback loop to continuously adjust the phase and frequency of the output signal to minimize any phase or frequency difference between the two signals.

In advanced communication systems, demand for high data rates and efficient spectrum utilization has paved the way for dense sub-carrier utilization techniques. This approach involves the transmission of multiple sub-carriers within a given frequency band, enabling simultaneous data transmission and enhanced spectral efficiency. However, the successful realization of dense sub-carrier utilization can involve the implementation of highly precise and robust local oscillators (LOs) to provide adequate carrier isolation. Carrier isolation can maintain the integrity and individuality of each sub-carrier, preventing interference and crosstalk between them. One factor is the design and implementation of local oscillators (LOs) within the communication system. LOs are components that generate the carrier signals used for modulating and demodulating the sub-carriers. The accuracy and stability of these local oscillators directly impact the overall system performance, particularly in terms of carrier isolation and signal quality.

In addition to carrier isolation, Multi-Input Multi-Output (MIMO) systems further compound the challenges faced by dense sub-carrier utilization. MIMO systems enhance spectrum efficiency by requiring each sub-carrier tone to carry high power, greater than 20 to 24 decibel-milliwatts (dBm). Interference among sub-channels can adversely affect the Signal-to-Noise Ratio (SNR) of the link, resulting in increased power requirements. To mitigate this issue, Inter-Carrier Interference (ICI) can be minimized, which places stricter constraints on the purity of LO circuits.

To deliver the high output power demands in the 5G systems, efficient RF Power-Amplifiers (PAs) can be implemented. Technologies such as SiGe, offer devices with higher breakdown voltage and higher transit frequency (fT) compared to CMOS/FinFET technologies. Therefore, SiGe devices are attractive for designing PAs that excel in maintaining efficient and high-power output delivery.

Low Phase Noise (PN) millimeter-wave (mm-Wave) clock generators are components in modern wireless and wire-line communication systems. In 5G systems more specifically, there is a demand for high data throughput, highlighting the need for dense sub-carrier frequency band allocation as well as high-speed high-resolution data converters.

### SUMMARY

This invention relates to Phase-Locked Loop (PLL) circuits. A wideband and ultra low-noise phase-locked loop (PLL) circuit can be used in a 0.18 μm BiCMOS/SiGe technology to operate at a nominal frequency of 35.68 GHz. The wideband and ultralow-noise PLL circuit includes a multi-phase phase frequency detector along with a high frequency reference signal, the bandwidth of the PLL can be maximized to reduce the phase noise and jitter contribution of the forward path loop components within the frequency band of interest. A multi-phase phase comparator also relaxes the constraints imposed by the sampling nature of the wideband and ultra low-noise PLL, allowing for a more convenient performance optimization with reduced jitter peaking and more optimal loop characteristics. The wideband and ultra low-noise PLL may provide a Phase Noise of −113.3 dBc/Hz at an offset frequency of 1 MHz, and a total integrated jitter of 59 root mean square phase noise (fs-rms) of the PLL integrated from 1 kHz to 100 MHz, consuming 194.6 megawatt (mW) with a jitter-power figure of merit (FoM) −241.6 dB. The power dissipation of the wideband and ultra low-noise PLL is less than conventional PLL, while higher than designs made in advanced complementary metal-oxide-semiconductor (CMOS) and fin field-effect transistor (FinFET) CMOS/FinFET technologies. The wideband and ultra low-noise PLL may be designed as a BiCMOS/SiGe 0.18 μm, aiming to be integrated together with power amplifiers in a 3D structure targeted for the next generation 5G communication systems.

There has thus been outlined, rather broadly, the more important features of the invention so that the detailed description thereof that follows may be better understood, and so that the present contribution to the art may be better appreciated. Other features of the present invention will become clearer from the following detailed description of the invention, taken with the accompanying drawings and claims, or may be learned by the practice of the invention.

### BRIEF DESCRIPTION OF THE DRAWINGS

FIG. 1 is a conceptual 3D structure for implementing next generation wireless systems in accordance with one example. Based on this approach, digital processing is mainly performed in an advanced CMOS/FinFET technology, while high-power and area-consuming circuits such as PA are being moved to a SiGe process.

FIG. 2 is a topology of the matrix PLL with added programmability and calibration in accordance with another example.

FIG. 3 is a reconfigurable PFD-CPC circuit with programmable gain, composed of two sets of phase comparators: sensitive to rising/falling edge in accordance with still another example.

FIG. 4 is a chip micro-photograph, showing total area and key block placements in accordance with one example.

FIG. 4 is a graph of measured PLL PN and random jitter (single- and multi-phase), compared to the free running VCO performance in accordance with an example.

FIG. 5 is a graph illustrating the measured output phase noise of the multi-phase PLL circuit under two different modes of operation; a single phase mode of operation and a double phase mode of operation in accordance with one example.

FIG. 6 is a graph of extrapolated PLL transfer function in accordance with another example.

FIG. 7 is a graph of PLL phase noise sensitivity to supply modulation and dependence of the output spur level to the input duty-cycle difference in accordance with an example.

FIG. 8 sets forth a flow chart illustrating an example method of operating a wide-band, multi-phase phase-locked loop (“PLL”) circuit by a processor in which aspects of the present invention may be realized.

These drawings are provided to illustrate various aspects of the invention and are not intended to be limiting of the scope in terms of dimensions, materials, configurations, arrangements or proportions unless otherwise limited by the claims.

### DETAILED DESCRIPTION

While these exemplary embodiments are described in sufficient detail to enable those skilled in the art to practice the invention, it should be understood that other embodiments may be realized and that various changes to the invention may be made without departing from the spirit and scope of the present invention. Thus, the following more detailed description of the embodiments of the present invention is not intended to limit the scope of the invention, as claimed, but is presented for purposes of illustration only and not limitation to describe the features and characteristics of the present invention, to set forth the best mode of operation of the invention, and to sufficiently enable one skilled in the art to practice the invention. Accordingly, the scope of the present invention is to be defined solely by the appended claims.

### Definitions

In describing and claiming the present invention, the following terminology will be used.

The singular forms “a,” “an,” and “the” include plural referents unless the context clearly dictates otherwise. Thus, for example, reference to “a detector” includes reference to one or more of such devices and reference to “the band” refers to one or more of such ranges.

As used herein with respect to an identified property or circumstance, “substantially” refers to a degree of deviation that is sufficiently small so as to not measurably detract from the identified property or circumstance. The exact degree of deviation allowable may in some cases depend on the specific context.

As used herein, “adjacent” refers to the proximity of two structures or elements. Particularly, elements that are identified as being “adjacent” may be either abutting or connected. Such elements may also be near or close to each other without necessarily contacting each other. The exact degree of proximity may in some cases depend on the specific context.

As used herein, the term “about” is used to provide flexibility and imprecision associated with a given term, metric or value. The degree of flexibility for a particular variable can be readily determined by one skilled in the art. However, unless otherwise enunciated, the term “about” generally connotes flexibility of less than 2%, and most often less than 1%, and in some cases less than 0.01%.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

As used herein, the term “at least one of” is intended to be synonymous with “one or more of.” For example, “at least one of A, B and C” explicitly includes only A, only B, only C, or combinations of each.

Numerical data may be presented herein in a range format. It is to be understood that such range format is used merely for convenience and brevity and should be interpreted flexibly to include not only the numerical values explicitly recited as the limits of the range, but also to include all the individual numerical values or sub-ranges encompassed within that range as if each numerical value and sub-range is explicitly recited. For example, a numerical range of about 1 to about 4.5 should be interpreted to include not only the explicitly recited limits of 1 to about 4.5, but also to include individual numerals such as 2, 3, 4, and sub-ranges such as 1 to 3, 2 to 4, etc. The same principle applies to ranges reciting only one numerical value, such as “less than about 4.5,” which should be interpreted to include all of the above-recited values and ranges. Further, such an interpretation should apply regardless of the breadth of the range or the characteristic being described.

Any steps recited in any method or process claims may be executed in any order and are not limited to the order presented in the claims. Means-plus-function or step-plus-function limitations will only be employed where for a specific claim limitation all of the following conditions are present in that limitation: a) “means for” or “step for” is expressly recited; and b) a corresponding function is expressly recited. The structure, material or acts that support the means-plus function are expressly recited in the description herein. Accordingly, the scope of the invention should be determined solely by the appended claims and their legal equivalents, rather than by the descriptions and examples given herein.

### EXAMPLE EMBODIMENTS

Accordingly, a technology is described to addresses the challenges of dense sub-carrier utilization through the development of a wide-band, multi-phase phase-locked loop (PLL) circuit (e.g., a wideband and ultra low-noise PLL circuit). The wide-band, multi-phase PLL circuit includes a reconfigurable and programmable multi-phase phase frequency detector (PFD) and reconfigurable charge pump controller (CPC) circuit (PFD-CPC circuit). This wide-band, multi-phase PLL circuit comprises a multi-phase PFD and multiple, identical slices of the reconfigurable CPC and may operate in either single-phase or multi-phase mode. It should be noted that PLL circuit operates in only either single phase or double phase. However, use of the term “multi-phase” indicates that the PLL circuit can be either operated in single phase or the double phase. However, the PLL circuit, as described herein, may operation in more than two (double) phases based on user preference, design circuitry, and/or circuit design. For example, implementing multi-phase operation (e.g., more than double phase) may involve configuring the PFD-CPC circuit to generate and process multiple phase signals, where the number of phases can be determined by the specific application requirements or desired functionality. This can be achieved by incorporating additional slices or units in the PFD-CPC circuit, each responsible for generating and processing a distinct phase signal. The multi-phase operation provides enhanced flexibility in frequency and phase tracking, improved noise performance, and increased versatility for various applications.

The wide-band, multi-phase PLL circuit can maximize bandwidth and reduce phase noise and jitter contribution of the forward path loop components within the targeted frequency band. In one aspect, the forward path loop components may include an input buffer, a multi-phase PFD, programmable charge pump slices, a loop filter, a VCO and one or more output buffers. As used herein, “ultra-low noise” refers to less than 100 fs rms jitter.

The bandwidth of the wide-band, multi-phase PLL circuit can be maximized by increasing a correction rate of the forward path i.e., PFD and the CPC. The designed bandwidth of the wide-band, multi-phase PLL circuit can vary from maximum based on a balance of factors such as the quality of the VCO. For example, a designed bandwidth may depend on the reference signal and VCO used, where the reference signal serves as a stable and known frequency against which the output frequency of the PLL is compared and controlled. High bandwidth tends to be desirable when the VCO is a poor quality (i.e. produces more jitter) and the reference is very good (i.e. low jitter) and vice versa. Stability and jitter are factors which can outweigh maximization of bandwidth. Accordingly, a high quality VCO is used with low bandwidth and can often be about 10% of the maximum (i.e, 1/10^{th} reference being the maximum), and in some cases 5% to 15% of the maximum. Thus, the optimal bandwidth of the wide-band, multi-phase PLL circuit may depend on the characteristics of both the reference signal and the voltage-controlled oscillator (VCO) used in the circuit. The quality, stability, and jitter performance of the reference signal, as well as the capabilities of the VCO, influence the selection of the desired or designated bandwidth setting for the PLL. The selection of the optimal bandwidth settings considers and balances these various factors such as, for example, the reference signal, the VCO.

Instead of giving a single-phase correction, the wide-band, multi-phase PLL circuit can provide correction on multi-phase, which reduces the free-running time of the VCO, and extends the wide-band, multi-phase PLL circuit bandwidth. The cut-off frequency of the VCO high-pass noise transfer function is also increased and VCO noise is reduced further in multi-phase mode. By incorporating these advancements, the wide-band, multi-phase PLL circuit provides robust carrier isolation and reliable transmission of multiple sub-carriers.

In an additional aspect, the wide-band, multi-phase PLL circuit includes a voltage-controlled oscillator (VCO). In this example, the wide-band, multi-phase PLL circuit includes a divider circuit coupled to the output of the VCO. A reconfigurable and programmable multi-phase PFD and reconfigurable CPC circuit (“PFD-CPC circuit”) can be coupled to the output of the divider circuit. The PFD-CPC circuit includes a multi-phase PFD and a plurality of identical slices of the reconfigurable CPC and configured to operate in either single-phase or multi-phase mode to reduce phase noise and jitter contribution of one or more forward path loop components within a targeted frequency band. A high-frequency reference signal may be provided to the PFD-CPC circuit coupled to an output of the divider circuit and the VCO. Bandwidth may be maximized, and phase noise and jitter contribution may be suppressed from one or more forward path loop components within a targeted frequency band based on a selected operating mode.

In one aspect, the wide-band, multi-phase PLL circuit may be 59-fs-rms 35-GHz PLL with FOM of −241-dB in 0.18-μm BiCMOS/SiGe circuit having the performance characteristics of a specific phase-locked loop (PLL) circuit implemented in a 0.18-μm BiCMOS/SiGe process technology. The 59-FS-RMS may indicate the root mean square (RMS) phase noise of the PLL, which is a measure of its noise performance. A lower value represents better noise performance, indicating lower phase noise. The “35-GHz” indicates an operating frequency range of the PLL, specifying the maximum frequency at which it can operate reliably. “FOM” stands for Figure of Merit, which is a metric used to evaluate the overall performance of the PLL. In this case, the FOM is specified as −241 dB, where a lower value represents better performance. The 0.18-μM BICMOS/SIG refers to the specific process technology used for implementing the PLL circuit, which combines elements of both bipolar complementary metal-oxide-semiconductor (BiCMOS) and silicon germanium (SiGe) technologies. The “0.18-μm” indicates the feature size of the transistors in the process, which determines the level of integration and performance characteristics of the circuit.

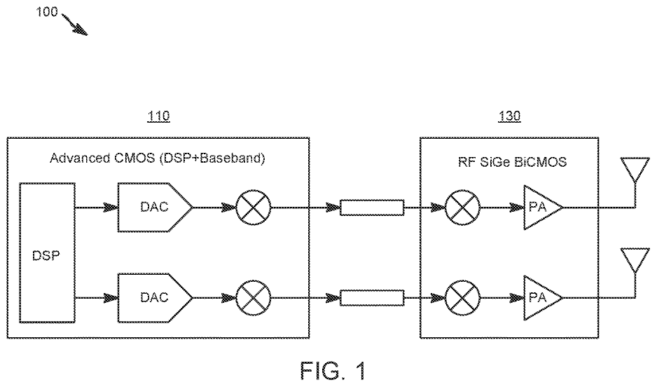

Embodiments in accordance with the present disclosure will be described in further detail beginning with FIG. 1. Like reference numerals refer to like elements throughout the specification and drawings. FIG. 1 demonstrates a conceptual 3D architecture in which high-power and high-speed circuits 100 are implemented in a Bipolar Complementary Metal Oxide Semiconductor (BiCMOS) or Silicon Germanium (SiGe) technology. The example SiGe BICMOS circuit 100 of FIG. 1 includes advanced CMOS device 110 having baseband functionality. The advanced CMOS device 110 includes a digital signal processor (DSP) (or software-based radio or digital preprocessing blocks) with two separate Digital-to-Analog Converters (DACs).

The SiGe BICMOS circuit 100 of FIG. 1 also includes a radio frequency (RF) SiGe BiCMOS) device 120 with one or more power amplifiers (PA). The RF SiGe BiCMOS device 120 combines the advantages of SiGe bipolar transistors and CMOS technology, offering high-performance RF circuitry with improved speed, linearity, and noise characteristics.

The SiGe BICMOS circuit 100 of FIG. 1 then can be integrated in a 3D structure, using Through-Silicon-Vias (TSVs), together with digital-heavy processing units in a more advanced CMOS or FinFET technology. Combining properties of SiGe/BiCMOS devices capable of handling high-power at high frequencies, with powerful digital signal processing capabilities of advanced FET technologies makes this configuration a desirable choice for implementing 5G RF transceivers. Such an architecture relies on very low noise LOs, such that ultra low jitter low-PN PLLs can be oriented on the same die as the PAs, implemented in SiGe technology.

As described herein, a PLL is designed to achieve ultra low phase noise and integrated jitter characteristics, emphasized mainly on close-in offset frequencies within the range of 100 kilohertz (kHz) to 1 megahertz (MHz). Two example designs include: (design A) design PLLs relying on very low noise Voltage Controlled Oscillators (VCOs), and/or alternatively (design B) design wideband PLLs that can suppress the forward path noise within the loop bandwidth of the circuit, with a clear reference signal.

A challenge in the first example design is based on design of a low phase-noise VCO (PN VCO), that can be employed in a low-bandwidth PLL. Using high-quality factor tanks in addition to a very careful design and simulation can be used to implement such VCOs. Also, an adequate loop design can be used to find a proper balance among different constraints, such as jitter peaking, bandwidth, and noise generation. The second example design option, as described herein, targets achieving the same goals in a different manner: a very wideband PLL is implemented that can adequately suppress the noise produced by the VCO and other building blocks on the forward path. This second example design option relaxes the design constraints of the VCO, Charge-Pump Circuit (CPC), and also suppresses the supply induced noise over a wider frequency range. Therefore, the system can expand the loop bandwidth to correct for the major part of the low frequency noise with significantly reduced jitter peaking, and yet maintain a stable operation. As a general guideline, a very wideband can be greater than 1 MHz and in some cases ranges from 1 MHz to 5 MHz, and in other cases is greater than 10 MHz.

In one aspect, for evaluating the two designs, if the operating frequency is low enough and producing low phase noise, the VCO involves fewer tradeoffs (which get unfavorable at higher operating frequency) and thus design A may be used. This choice involves much higher design time and design capital, much higher time to market. Although the cost of production is lower, it is more sensitive to variation hence might have lower yield.

For designs with higher frequency of operation, the requirements for low noise Voltage Controlled Oscillators (VCOs) becomes challenging. Starting with a higher cost of production (mainly for the low noise reference), the other requirements for design B scale more linearly with frequency. Additionally, it is less sensitive to variation and can deliver higher yield. Therefore, designs B for the wideband and ultra low-noise PLL circuit is more competitive on those factors.

Additionally, for the design and simulation of the low PN VCO, such as the specific quality factor used and the design considerations for finding the proper balance among different constraints design of a low PN VCO can be split into 3 main parts; 1) design of a high-quality factor tank, 2) design of a cross couple biased strongly in saturation region, and 3) design of low noise current mirrors. The current mirrors and cross couples have a trade off in design; if they are biased strongly in saturation, the implied larger size (assuming a fixed bias current) offers lower flicker but will have higher loading. Additionally, to maintain saturation, more headroom is allocated reducing the swing of the produced tone, reducing SNR, and indirectly increasing PN. Therefore, this balance can be carefully chosen to get higher PN. Finally, the resonating tank can be carefully designed with accurate EM modeling and simulation to exhibit a high-quality factor servicing the full desired frequency range. The varactors used will manifest another tradeoff; and can be biased to exhibit a wide linear range, but this can be done without significantly hampering the quality factor.

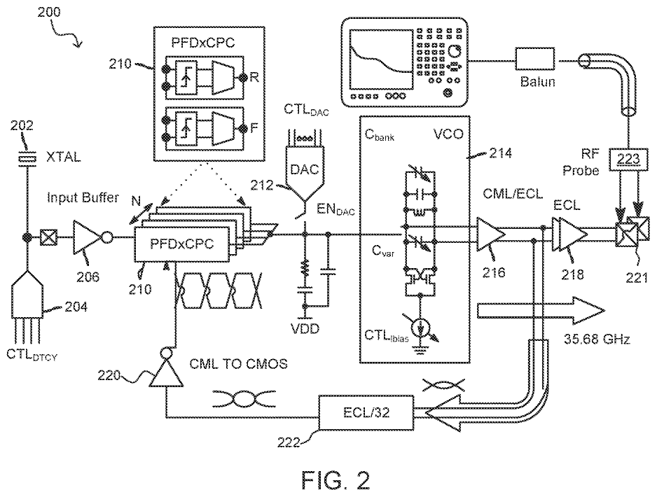

Turning now to FIG. 2, a multi-phase PLL circuit 200 (e.g., a wideband and ultra low-Noise PLL in a BiCMOS/SiGe System) is depicted. The multi-phase PLL circuit 200 uses a low PN high-frequency reference crystal as well as a multi-phase PFD. In one example, the multi-phase PLL circuit 200 may include a crystal oscillator (XTAL) 202, a duty cycle control code for DAC (CTL_{DTCY}) 204, one or more reconfigurable and programmable multi-phase PFD and reconfigurable and programmable charge pump controller (CPC) (PFDxCPC) 210 (e.g., also depicted as PFDxCPC 210 slices) being rising edge sensitive (R) and falling edge sensitive (F), a control code for DAC (CTL_{DAC}) 212 to initialize VCO control voltage of the VCO 214, a capacitor bank (C_{bank}) for the VCO 214, a varactor Capacitance (Cᵥₐᵣ) for the VCO 214, a DAC connection switch (EN_{DAC}) to control voltage of VCO 214, current mode logic (CML), 216 an Emitter Coupled Logic (ECL) 218, and a control code (CTL_{bias}) control code to change the bias current for the VCO 214. It should be noted that other components are depicted but are illustrated only for example purposes only and are not critical elements of the technology described.

In some embodiments, the crystal oscillator (XTAL) 202 may be a low phase noise high-frequency reference crystal while also serving as a stable frequency source for the multi-phase PLL circuit 200. The CTL_{DTCY} 204 may control the duty cycle of the output signal from a digital-to-analog converter (DAC) and adjusts the ratio between the high and low states of the signal. In one aspect, the multi-phase PLL circuit 200 may use an input buffer from the crystal oscillator (XTAL) 202 and the CTL_{DTCY} 204. Again, the crystal oscillator (XTAL) 202 may be responsible for receiving the input signal from the crystal oscillator (XTAL) 202 and converting the input signal into a desired voltage or current level that can be processed by the subsequent circuitry of the multi-phase PLL circuit 200. The crystal oscillator (XTAL) 202 may provide a stable and precise reference signal that provides the operation of the multi-phase PLL circuit 200. The input buffer can ensure that the signal from the crystal oscillator is properly conditioned and matched with the requirements of the following circuit blocks.

The multi-phase PFD combined with a Charge Pump, herein collectively referred to as the PFDxCPC 210, may include one or more PFDxCPC 210 (e.g., slices of identical PFDxCPCs' 210) that perform the phase detection and charge pump functions, allowing the multi-phase PLL circuit 200 to compare the phase difference between the reference signal (R) and feedback signal (F).

In one aspect, the PFDxCPC 210 may be divided into two components that incorporate as a first component a multi-phase phase frequency detector (e.g., the reconfigurable and programmable PFD) along with a high frequency reference signal, to maximize bandwidth of the multi-phase PLL circuit 200 and to reduce the phase noise and jitter contribution of the forward path loop components within the frequency band of interest. The second component of the PFDxCPC 210 may include a multi-phase phase comparator (e.g., a reconfigurable charge pump controller (CPC) circuit) that relaxes the constraints imposed by the sampling nature of the multi-phase PLL circuit 200 enabling and maximizing performance with reduced jitter peaking and more optimal loop characteristics.

Due to the sampling nature of a PLL, the multi-phase PLL circuit 200 is a discrete time system. For simplicity in optimizing the loop, the multi-phase PLL circuit 200 may be designed as a continuous time second order system. To allow this continuous time approximation, the natural frequency of the loop may be lower than the sampling (reference) frequency. This indirectly limits the bandwidth of the loop for stable operation. The bandwidth can be increased by keeping the loop of the multi-phase PLL circuit 200 in a critically damped condition (e.g. damping factor is 1). The multi-phase phase comparator of the multi-phase PLL circuit 200 doubles the sampling frequency for the same reference, thus doubling the bandwidth without increasing workload or effort.

Again, the multi-phase phase frequency detector and the multi-phase phase comparator may be collectively referred to in FIG. 2 as the PFDxCPC (e.g., the PFDxCPC 210 of FIG. 2).

The CTL_{DAC} 212 control code may be implemented and used to initialize a control voltage of the voltage-controlled oscillator (VCO) 214 and set the initial conditions for the VCO's frequency and phase for the wideband, multi-phase PLL circuit 200.

The C_{bank} for the VCO 214, may be a bank or collection of capacitors connected to the VCO 214 and provides tuning and frequency adjustment capabilities for the VCO 214.

The Cᵥₐᵣ may be a variable capacitor connected to the VCO 214 and provides fine-tuning of the VCO's 214 frequency by varying its capacitance.

The EN_{DAC} switch may control the voltage applied to the VCO 214 from the digital-to-analog converter (DAC) and for the adjustment of the VCO control voltage.

The current mode logic (CML) 216 and emitter coupled logic (ECL) 218 may each be different circuit logic used in the multi-phase PLL circuit 200 for their specific characteristics and may be employed within the multi-phase PLL circuit 200 for various signal processing and amplification purposes.

The CTL_{bias} for the VCO 214 is a control code to change the bias current for the VCO 214 and allows for the regulation of the VCO's operating conditions.

CML to CMOS 220 connects the voltage level from the current mode logic level (i.e. from ECL/32 222) to rail-to-rail CMOS operation (e.g. converts CML voltage domain to CMOS voltage domain). In one example, the “CML to CMOS” is a circuit that performs a voltage level conversion from Current Mode Logic (“CML”) level to Complementary Metal-Oxide-Semiconductor (“CMOS”) logic level. This conversion allows for the translation of voltage signals from a CML voltage domain to a CMOS voltage domain. The purpose of this conversion is to enable compatibility or interoperability between different circuit components or systems that operate in these different voltage domains.

ECL/32 may be a frequency divider with a “divide by 32” factor working in emitter coupled logic (ECL) (e.g. which is equivalent to current mode logic). That is, the “ECL/32” indicates that a frequency divider designed to divide the input frequency by a factor of 32. The term “ECL” stands for Emitter-Coupled Logic, which is a type of digital logic known for its high-speed operation and current mode signaling. ECL is considered equivalent to Current Mode Logic (CML) in certain contexts

In operation, the multi-phase PLL circuit 200, employing a high reference frequency (e.g., Crystek CRBSCS-01-1000.000) such as, for example, the crystal oscillator (XTAL) 202, results in two effects: (i) lower division ratio that results in lower in-band PN multiplication factor, and (ii) allowing to increase the loop bandwidth, or trade the wider bandwidth with lower jitter peaking, if required. The multi-phase PFD of the PFDxCPC 210 increases the effective loop update rate, relaxing the loop filter design constraints, thus achieving lower jitter peaking that arises due to the systems discrete-time and sampling nature.

The VCO 214, as described herein, may be an inductor-Capacitor Voltage-Controlled Oscillator (LC VCO) with a tank quality factor, and may use an LC tank circuit as its frequency-determining element. That is, an LC tank circuit may include an inductor (L), and a capacitor (C) connected in parallel or series. The combination of the inductor and capacitor forms a resonant circuit that exhibits a natural resonant frequency. By varying the control voltage applied to the VCO 214, the effective capacitance or inductance of an LC tank circuit can be changed, thereby tuning the oscillation frequency of the VCO 214. The VCO 214 (e.g., an LC VCO) may operate based on the principle of resonant frequency variation with the control voltage. As the control voltage changes, the LC tank circuit's resonant frequency shifts, resulting in a corresponding change in the output frequency of the VCO 214. This voltage-controlled frequency tuning makes LC VCOs suitable for applications where frequency agility and modulation are desired.

The capacitive components of the tank circuit of the VCO 214 may be split up into multiple parts, 1) a digitally controlled capacitor bank of metal-insulator-metal (MiM) capacitors to increase the VCO frequency range, 2) a varactor for continuous frequency control by the PLL loop, and 3) parasitic capacitance. The PLL being used here synonymously with the PLL circuit where the full PLL circuit path is a forward path including the PFDxCPC 210 and the VCO 214 (“PFD-CPC-VCO”), and the feedback is the frequency divider (e.g., the “ECL/32”) and CML to CMOS)

As the target operating frequency is very high (e.g. greater than 10 GHz and in some cases 30-35 GHz), the loading capacitance can be kept sufficiently minimal as to not dominate the total capacitance of the tank. Therefore, a buffer chain is created using SiGe devices to tap and deliver the high frequency output to the divider and the RF pads, employed for probe station-based measurements. The divider following the VCO has been designed based on a chain of SiGe-based Emitter-Coupled Logic (ECL) divide-by-2 circuits, capable of working at speeds as high as 40 GHz, as depicted in FIG. 2. As used in FIG. 2, the divider is denoted using the ECL/32 block in FIG. 2, as mentioned above. The RF pads 221 receive the high-speed fast buffer output and RF Probes 223 are used to directly monitor the high-speed RF signal. Also, a balun may be used where the balun device is used to convert between balanced and unbalanced signals and may be used to interface between components or stages that operate with different signal configurations. For example, a balun can be employed to convert between single-ended and differential signals, or to match impedance levels between different parts of the PLL circuit.

It should be noted that the bandwidth of a type-II PLL (e.g. both phase and frequency detector with a charge pump) using a conventional PFD is limited to a fraction of its input reference frequency. The main reason behind this limitation is that the loop update rate is bounded to where T_{ref} is the time period of the reference signal. A systematic process to relax this limitation is to use a multi-phase phase comparator such as, for example, the multi-phase phase comparator of the PFDxCPC 210 of FIG. 2, where multiple phases of the clock are being used for phase adjustment and thus the loop update rate is increased proportionally. In reference to the multi-phase phase comparator “relax” the constraints imposed by the sampling nature of the PLL, due to the sampling nature of the PLL, the system is a discrete time system. For simplicity in optimizing the loop, it can be designed as a continuous time second order system. To allow this continuous time approximation, the natural frequency of the loop can be much lower than the sampling (reference) frequency. This indirectly limits the bandwidth of the loop for stable operation. The bandwidth can be increased by keeping the loop in a critically damped condition, but this can be very sensitive to variation and tends to involve a lot of back and forth in design or calibration. The multi-phase phase comparator such as, for example, the PFDxCPC 210 of FIG. 2 may double the sampling frequency for the same reference, thus doubling the bandwidth without needing the extra effort mentioned.

As described herein, a multi-phase PFD of the PFDxCPC 210 of FIG. 2 can be utilized to increase the PLL bandwidth by a factor of square root of two. The relaxed constraints imposed by the sampling nature of the loop can be traded to reduce the jitter peaking as well, and thus enhance the circuit overall jitter performance. The jitter peaking can directly translate to an amplification of noise present at that frequency. For a PLL with N number of phases (NPH) involved in the comparison process, the loops natural frequency (ωₙ) and the damping factor (ζ) change to:

$${ω}_{n} = \sqrt{{I}_{C P C} {K}_{V C O} * {N}_{P H} / ( 2 π {C}_{1} M} ) , \qquad ( 1 )$$

$$ζ = ( {R}_{1} / 2 ) \sqrt{{I}_{C P C} {K}_{V C O} {C}_{1} * {N}_{P H} / ( 2 π M} ) , \qquad ( 2 )$$

demonstrating and showing that both the loop natural frequency and its damping factor will improve in proportion to the square root of N_{PH}, where I_{CPC} is the average charge pump current, K_{VCO} is a VCO gain, N_{PH} is a number of phases (for double phase operations it would be N_{PH=2}), C₁ is a loop filter capacitance, and M is the division factor.

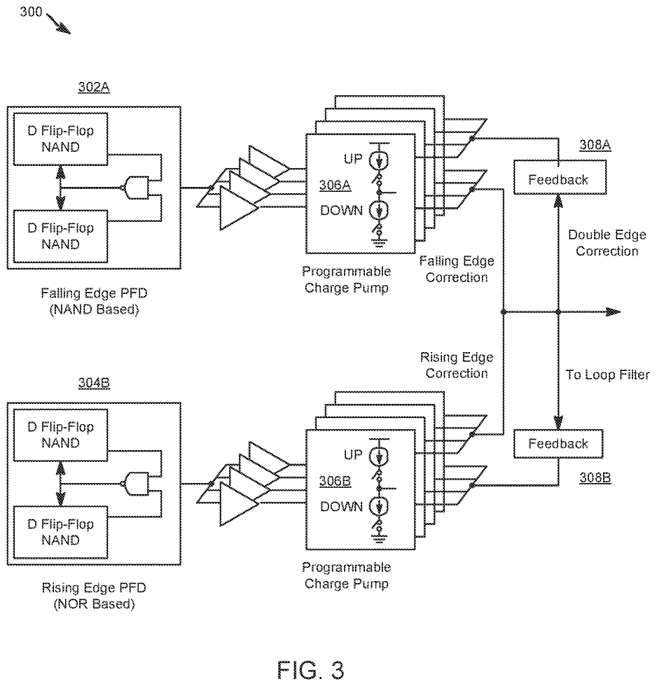

For further explanation, FIG. 3 depicts a reconfigurable and programmable PFD-CPC circuit 300 (e.g., the Multi-phase PFD combined with Charge Pump 210 of FIG. 2) that includes made up of slices (sub-blocks) has been implemented to examine the effectiveness of the double-sampling loop topology. The reconfigurable and programmable PFD-CPC circuit 300 (e.g., a Multi-phase PFD combined with Charge Pump 210 of FIG. 2) may include one or more reconfigurable and programmable multi-phase PFDs (e.g., CMOS PFD) such as, for example, or more reconfigurable and programmable multi-phase PFDs 302A and 304B and one or more reconfigurable and programmable charge pump controllers (CPC) 306A, 306B (e.g., also depicted as the CPC's of the PFDxCPC 210 in FIG. 2) being rising edge sensitive (R) and falling edge sensitive (F).

Thus, the reconfigurable and programmable PFD-CPC circuit 300 is designed to be isotropic using both NAND and NOR based topology (e.g., D flip-flop NAND and D flip-flop NOR logic) to provide correction of phase and frequency in both rising (by NOR logic) and falling edge (by NAND logic) of the reference signal. The reference signal is provided to the input CMOS buffer, and it converts the signal to CMOS level which becomes the input to the NAND and NOR based PFD such as for example, PFD 302A (NAND based) and PFD 304B (NOR based). In both rising and falling edge of the reference signal, UP/DOWN pulses are generated and are provided as inputs to the multiple charge pump slices such as, for example, the multiple CPC 306A, 306B slices. Each of the multiple CPC 306A, 306B slices are identical but their outputs are tied together. The number of active multiple CPC 306A, 306B slices is programmable and thus, the overall charge pump current can be increased or decreased by turning on/off more and/or less a number of multiple CPC 306A, 306B slices due to the Kirchhoff's current law (KCL) property. The programmability of the charge pump current provides an additional flexibility in terms of bandwidth tuning.

Two separate feedback loops 308A and 308B can be implemented for both the rising and falling edge sensitive charge pump slices. The feedback loops 308A and 308B may reduce the UP/DOWN current mismatch. An off-chip correction loop (not shown in FIG. 3) may be used to tune the duty cycle of the reference CMOS level clock. A crystal provides a sinusoidal signal, and the DC value is imposed through a DAC. The sinusoidal signal may be passed through a CMOS buffer.

Returning now to FIG. 2, the number of feedback phases as well as the strength of the charge-pump current can be programmed independently. Thus, making the system versatile with post-fabrication calibration. Additionally, having designed the PFDxCPC 210 of FIG. 2 (see also the reconfigurable and programmable PFD-CPC circuit 300 of FIG. 3) as a combined unit cell improves the overall speed and reduces power consumption of a block, which is a factor when such a high-speed circuit is implemented using 0.18-μm CMOS devices.

An off-chip correction loop was employed to minimize the effect of duty-cycle distortion (DCD) on performance of the multi-phase PFD, thus curtailing the spur level at the output of PLL. The associated control loop measures the difference on duty-cycle of the input reference clock and the divider output signal. Then, the DC bias voltage at the input of the clock buffer can be adjusted accordingly to reduce the DCD difference at the input of PFD. In some cases, this DCD difference can be minimized, while in other cases can be within 5-10% of minimum. Two standard PFDs, one based on NOR architecture (rising-edge), and the other one based on NAND (falling-edge), have been employed.

For a safe multi-phase PLL circuit 200 startup as shown in FIG. 2, the DAC 212 is provided to initialize the VCO control voltage. It should be noted the DAC 212 may be an 8-bit DAC implemented using a resister ladder network based on the R-2R architecture “8b R-2R DAC” where the resistors are arranged in a ladder-like structure, where the values of the resistors follow a specific ratio (typically 2:1). The digital input is converted into an analog output voltage by selectively connecting the ladder's junction points to either a reference voltage or ground, based on the binary values of the input bits. The “8b” in “8b R-2R DAC” indicates that the DAC has a resolution of 8 bits, meaning it can convert digital input signals with 8-bit precision. The number of bits determines the number of possible output voltage levels and thus the overall resolution of the DAC.

In this example, the loop is opened by turning off all the PFD-CPC slices and the control voltage of the VCO is set using the DAC. After a delay, only one of the two PFDs will be turned on, with the DAC still active. Once the PLL lock is achieved the DAC is turned off, then the PFD-CPC slices of the other phase are also enabled. At this point, the PLL switches to operate in multi-phase mode.

FIG. 2 and FIG. 3 both depict multi-phase PFD (e.g., a NAND based Falling edge PFD and NOR based rising edge PFD). After the multi-phase PFD (e.g., the multi-phase PFD of the PFDxCPC 210), the UP/DOWN signals are sent to the charge pump slices (e.g., the CPC slices of the PFDxCPC 210) using buffer chain (FIG. 3). The charge pump current is programmable since multiple identical slices are connected to the control voltage of VCO. Instead of muti-phase, the multi-phase PFD may operate in single phase mode. The number of active slices on the charge pump is programmable thus the average charge pump current can be tuned on-chip. The overall multi-phase PFD and charge pump slices are named PFDxCPC as a combined block in FIG. 2

### EXAMPLE

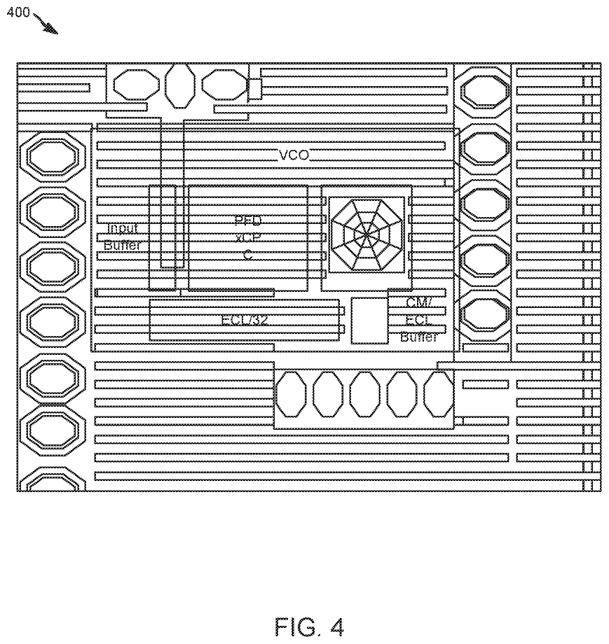

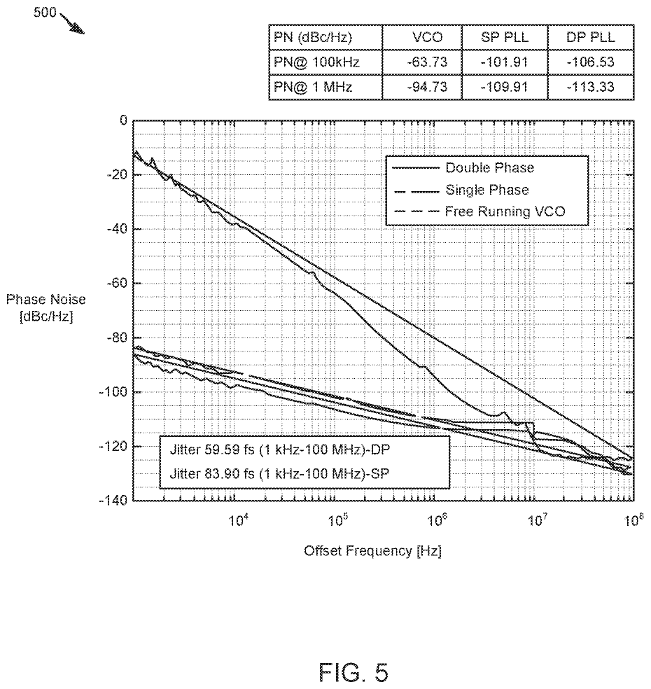

In one example, the multi-phase PLL circuit such as, for example the multi-phase PLL circuit 200 of FIG. 2 may be designed in 0.18 μm SiGe BiCMOS 1P7M technology. The SiGe bipolar junction transistor (BJT) devices may be used to implement the high-speed divider and the 35.68 GHz output buffer stages. A bank of MiM capacitors provide the VCO center frequency a control of plus or minus ten percent (e.g., +/−10%). The silicon area of the multi-phase PLL circuit including the output buffer stages, decoupling caps, test pads, biasing and the core PLL, is 900 micrometer (μm)×500 μm, as shown in FIG. 4, depicted the multi-phase PLL circuit 200 of FIG. 2. Descriptions and embodiments of FIGS. 1-3 can be used in FIG. 5. Repetitive description of like elements employed in other embodiments described herein (e.g., FIG. 4) is omitted for sake of brevity.

As depicted in FIG. 4, the multi-phase PLL circuit such as, for example, the multi-phase PLL circuit 200 consumed 194.6 mW in the multi-phase mode and 176.9 mW in the single-phase mode. In both modes, VCO and the divider block consume 12.6 mW and 84 mW, respectively. In PFDxCPC consumes 80.22 mW and 97.96 mW in the single and multi-phase modes, respectively. The Input Buffer may be a CMOS buffer to convert sinusoidal XTAL signal to rail-to-rail CMOS signal. The PFDxCPC (e.g., PFDxCPC 210 of FIG. 2) may be a combined block of multi-phase PFD and programmable charge pump slices. The ECL (e.g., ECL 218 of FIG. 2) is the emitter coupled logic used in Divider. The CML (e.g., CML 216) is used in fast buffer. The VCO (e.g., VCO 214 of FIG. 2) is a LC tank-based VCO.

For further explanation, FIG. 5 depicts graph 500 illustrating the measured output phase noise of the multi-phase PLL circuit such as, for example the multi-phase PLL circuit 200 of FIG. 2 at 35.68 GHz, under two different modes of operation; a single phase mode of operation and a double phase mode of operation. Graph 500 also depicts a free running VCO such as, for example, VCO 214 of FIG. 2. The x-axis of graph 400 measures the offset frequency (Hz) and the y-axis of graph 500 measures the phase noise (dB/Hz).

In this example, while the output phase noise of the multi-phase PLL circuit is negative (−) 101.94 dBc/Hz and −109.91 dBc/Hz at 100 kHz and 1 MHz offset frequency respectively using the conventional PFD structure, both the output phase noise and the offset frequency improves to −106.53 dBc/Hz and −113.33 dBc/Hz in the multi-phase mode. The equivalent random jitter of the multi-phase PLL output integrated from 1 kHz to 100 MHz are 83.9 fs-rms and 59.59 fs-rms in single-phase and multi-phase modes, respectively.

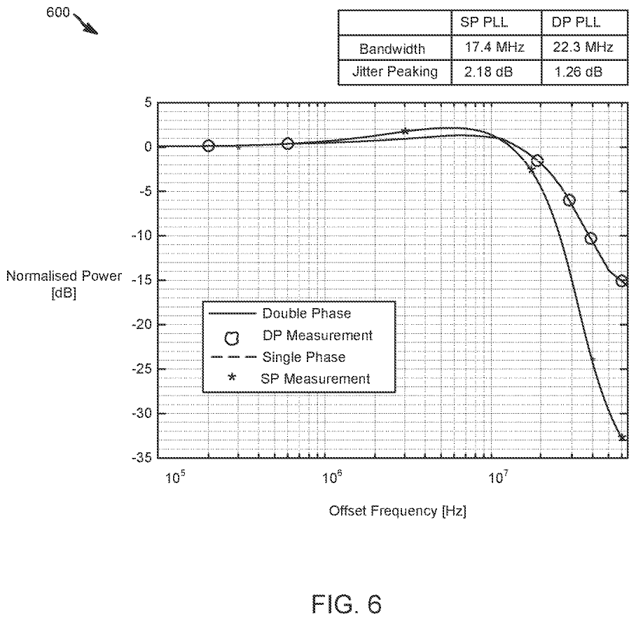

A wide multi-phase PLL bandwidth helps to further suppress the supply noise. The bandwidth is extrapolated from a set of measurements, as shown in graph 600 of FIG. 6. The x-axis of graph 600 measures the offset frequency (Hz) and the y-axis of graph 600 measures the normalized power [dB]. The wide multi-phase PLL bandwidth is measured to be 17.4 MHz and 22.3 MHz, in single- and multi-phase modes, respectively. Instead of expanding the bandwidth of PLL in multi-phase mode by a factor of 1.4, the bandwidth has been traded to reduce the jitter peaking as depicted in FIG. 6.

To measure the supply sensitivity of the circuit, a single-tone noise was added on top of the supply rail, and its frequency was swept step-by-step. The corresponding spur level produced at the output of multi-phase PLL due to the supply noise was measured from 100 kHz to 300 MHz. Notably, a low frequency (e.g., a frequency less than natural frequency of PLL loop) sinusoidal signal may be mixed with the supply and the spectrum of the produced oscillation. At an offset frequency equal to the mixed tone (e.g., a low-frequency sinusoidal signal that is mixed with the supply voltage of a circuit), a spur is added, where the spur may be an undesired spectral component that appears at a specific frequency offset from the original tone. The ratio of the mixed power to the spur power shows the supply sensitivity of the design. Repeating this at different offset frequencies shows the supply sensitivity as a function of frequency.

That is, when the tone is mixed with the supply voltage, the resulting spectrum may contain additional components apart from the desired oscillation frequency. These additional components, including the spur, can be caused by non-linearities or imperfections in the circuit. By measuring the power of the mixed signal compared to the power of the spur at different offset frequencies, it is possible to determine the supply sensitivity of the circuit design. The ratio of mixed power to spur power provides an indication of how susceptible the circuit is to variations in the supply voltage. By repeating this measurement at different offset frequencies, the supply sensitivity of the design can be evaluated across a range of frequencies.

The absolute level of the supply noise was measured and normalized using a wide-band 50 impedence (Ω) on-chip buffer.

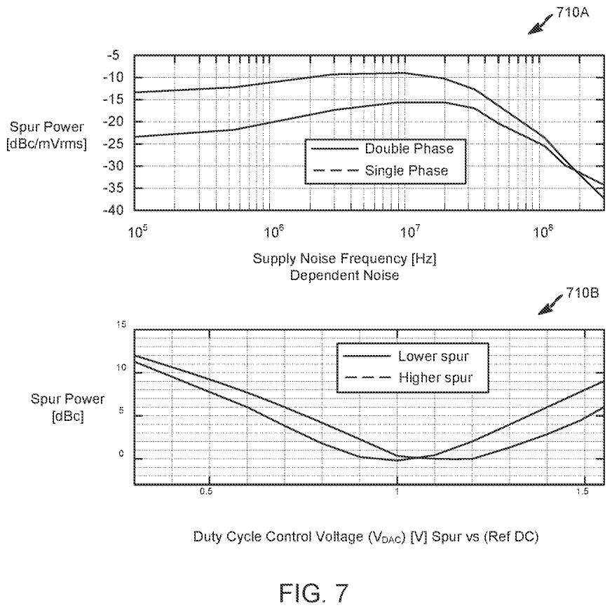

For further explanation, graph 710A of FIG. 7 compares the spur level (depicted on the x-axis) produced by the intentionally added supply noise for two modes of operation; the single phase operation mode and the double phase operation mode. Wider multi-phase PLL bandwidth is achieved in the multi-phase mode and suppresses the supply noise by up to 10 dB within the circuit bandwidth compared to the single-phase PFD mode.

Graph 710B of FIG. 7 shows the spur level degradation due to the input duty-cycle distortion in multi-phase mode. As illustrated, the output spur level can be corrected by up to 7 dB using off-chip duty-cycle correction circuit. The measured input spur level with proper duty-cycle correction at 1.115 GHz offset is −43.44 dBc in the single-phase mode, which improves to −48.56 dBc in the multi-phase mode.

TABLE 1
compares the performance of the proposed PLL to the state-of-the-art.

| | CMOS | | | | SiGe | | | | | |
|---|---|---|---|---|---|---|---|---|---|---|
| | [1] | [2] | [13] | [14] | [15] | [16] | [17] | [18] | DP | SP |
| Tech | 65 nm | 65 nm | 28 nm | 28 nm | 90 nm | 0.18 um | 0.18 um | 0.25 um | 0.18 um | 0.18 um |
| Node | | | | | | | | | | |
| Ref | 100 | 120 | 250 | 200 | 100 | 120 | 1.7k | 125 | 1k | 1k |
| Freq | | | | | | | | | | |
| (MHz) | | | | | | | | | | |
| Center | 28 to | 25 to | 21 to | 19 | 25 to | 29 to | 24 to | 28 to | 34 to | 34 to |
| Freq | 31 | 30 | 26 | | 28 | 33 | 27 | 32 | 37 | 37 |
| (GHz) | | | | | | | | | | |
| Phase | −106 | −102 | −110 | −133 | −107 | −97 | −107 | −81 | −113 | −106 |
| Noise at | | | | | | | | | | |
| 1 MHz | | | | | | | | | | |
| (dBc/Hz) | | | | | | | | | | |
| Jitter | 77 | 206 | 76 | 20 | 94 | — | — | — | 59 | 84 |
| (fs-rms) | | | | | | | | | | |
| Power | 42 | 36 | 16 | 12 | 850 | 63 | 56 | 287 | 195 | 177 |
| (mW) | | | | | | | | | | |

The circuit parameters were compared to the PLLs implemented in both advanced CMOS as well as similar SiGe technologies.

Operating at 35.68 GHz, the wideband and ultra low noise multi-phase PLL circuit such as, for example, the multi-phase PLL circuit 200 exhibits a Figure of Merit (FoM) of −241.6 dB. The wideband and ultra low noise multi-phase PLL circuit has the lowest FoM when compared to the similar designs in SiGe process technologies, thanks to the PLL architecture, an optimal loop design, and careful implementation. At the same time, the wideband and ultra low noise multi-phase PLL circuit competes with the ones implemented in advanced CMOS technologies in terms of total integrated jitter, phase noise, and FoM. The power consumption of the designed PLL is higher than the CMOS counterparts mainly because of operating the circuit at such a high frequency, i.e., 35.68 GHz, using 0.18 μm technology. That is, the wideband and ultra low noise multi-phase PLL circuit implements 2 key changes compared to contemporary designs; i) higher frequency reference, and ii) higher Bandwidth. The higher frequency reference translates to a reduced divide ratio requirement reducing the noise contribution from the divider and reduction in forward path noise multiplication. It also allows for a stable, higher frequency operation. This allows the PLL loop of the wideband and ultra low noise multi-phase PLL circuit to have a much higher loop-gain in the band of interest, thus suppressing the noise more effectively.

Thus, as depicted, a wide-band multi-phase PLL, supported by duty-cycle correction circuit may be provided and designed using 0.18 μm BiCMOS/SiGe technology to operate at a nominal frequency of 35.68 GHz. Incorporating a multi-phase phase/frequency detector and a very high frequency reference, the bandwidth of the wide-band multi-phase PLL is maximized to reduce phase noise and jitter generation at the frequency band of interest. For example, the wide-band multi-phase PLL is measured to exhibit a phase noise of −113.33 dBc/Hz at an offset of 1 MHz, and integrated jitter of 59 fs-rms from 1 kHz to 100 MHz, while consuming 194.6 mW with a jitter-power FoM of −241.6 dB.

### Methods

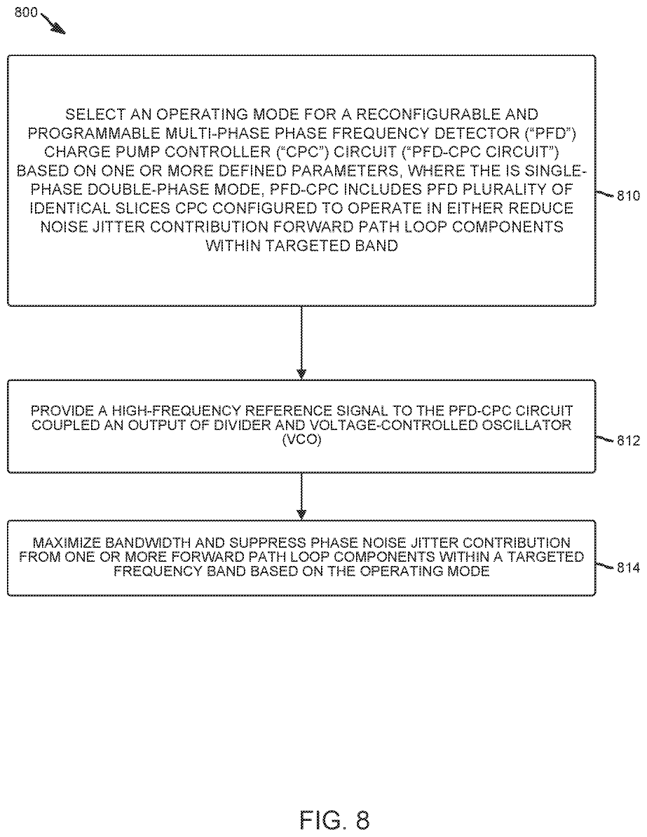

For further explanation, FIG. 8 sets forth a flow chart illustrating an example method, on accordance with some embodiments. The method 800 may be implemented as a method executed as instructions on a machine, where the instructions are included on at least one computer readable medium or one non-transitory machine-readable storage medium.

As shown, method 800 includes selecting an operating mode for a reconfigurable and programmable multi-phase phase frequency detector (PFD) and reconfigurable charge pump controller (CPC) circuit (PFDCPC circuit) based on one or more defined parameters, where the operating mode is a single-phase mode or multi-phase mode (e.g., multi-phase), and the PFD-CPC circuit includes a multi-phase PFD and a plurality of identical slices of the reconfigurable CPC and configured to operate in either the single-phase or the multi-phase mode to reduce phase noise and jitter contribution of one or more forward path loop components within a targeted frequency band, as in block 810.

The method 800 includes providing a high-frequency reference signal to the PFD-CPC circuit coupled to an output of the divider circuit and a voltage-controlled oscillator (VCO)—812 maximizing bandwidth and suppressing phase noise and jitter contribution from one or more forward path loop components within a targeted frequency band based on the operating mode, as in block 814. The method 800 includes maximizing bandwidth and suppressing phase noise and jitter contribution from one or more forward path loop components within a targeted frequency band based on the operating mode, as in block 816.

In one aspect, in conjunction with and/or as part of at least one block of FIG. 8, the operations of method 800 may include each of the following. The operations of method 800 may also include generating the high-frequency reference signal using a voltage-controlled oscillator (VCO) coupled to the PFD-CPC circuit and providing the generated high-frequency reference signal to the PFD-CPC circuit.

The operations of method 800 may also include providing an output signal from a voltage-controlled oscillator (VCO) coupled to the PFD-CPC circuit, where the output signal is used as a feedback signal in conjunction with the high-frequency reference signal to the PFD-CPC circuit for adjusting the operating mode and optimizing noise suppression within the targeted frequency band.

The operations of method 800 may also include adjusting a control input of the voltage-controlled oscillator (VCO) coupled to the PFD-CPC circuit based on feedback from a divider circuit to maintain stable operation and accurate tracking of frequency and phase.

The operations of method 800 may also include adjusting frequency margining of an output signal from the voltage-controlled oscillator (VCO) to expand the range of operating frequencies within the targeted frequency band. In one aspect, adjusting the frequency margining is an operation to assess and adjust the operational frequency of the the PFD-CPC circuit and may varying the frequency of operation within a predetermined range to evaluate performance and robustness under different frequency conditions for the PFD-CPC circuit. Thus, by frequency margining, the PFD-CPC circuit may operate reliably and within specified performance parameters across a range of frequencies. It helps determine the operational limits and tolerances of the system and enables optimization for different operating conditions.

The operations of method 800 may also include adjusting an overall charge pump current of the reconfigurable charge pump controller (CPC) circuit for bandwidth tuning within the targeted frequency band. The operations of method 800 may also include adjusting phase differences between the feedback signal and the high-frequency reference signal within the multi-phase phase frequency detector (PFD) of the PFD-CPC circuit.

### CLAUSES

For purposes of clarity, additional variations of the PLL circuit can include

Clause 1: A wide-band, multi-phase phase-locked loop (PLL) circuit comprising:
a voltage-controlled oscillator (VCO);
a divider circuit coupled to the output of the VCO; and
a reconfigurable and programmable multi-phase phase frequency detector (PFD) and reconfigurable charge pump controller (CPC) circuit (PFD-CPC circuit) coupled to the output of the divider circuit, wherein the PFD-CPC circuit includes a multi-phase PFD and a plurality of identical slices of the reconfigurable CPC and configured to operate in either single-phase or multi-phase mode to reduce phase noise and jitter contribution of one or more forward path loop components within a targeted frequency band.

Clause 2: The wide-band, multi-phase PLL circuit of any clause, further comprising a loop filter coupled to an output of the PFD-CPC circuit and to a control input of the VCO.

Claims 3: The wide-band, multi-phase PLL circuit of claim 1, wherein the VCO is a low phase noise voltage-controlled oscillator with a split capacitor bank and varactor.

Clause 4: The wide-band, multi-phase PLL circuit of any clause, further comprising a high-frequency reference signal coupled to the PFD-CPC circuit.

Clause 5: The wide-band, multi-phase PLL circuit of any clause, wherein each of the plurality of identical slices of the reconfigurable CPC of the PFD-CPC circuit is configured to independently adjust an overall charge pump current for bandwidth tuning.

Clause 6: The wide-band, multi-phase PLL circuit of any clause herein, wherein each of the plurality of identical slices of the reconfigurable CPC of the PFD-CPC circuit is configured to adjust frequency margining of an output signal to expand a range of operating frequencies.

Clause 7: The wide-band, multi-phase PLL circuit of any clause, wherein the multi-phase PFD of the PFD-CPC circuit is configured to adjust phase differences between a feedback signal and a reference signal for tracking frequency and phase of an output signal.

Clause 8: The wide-band, multi-phase PLL circuit of any clause, wherein the PFD-CPC circuit is configured to dynamically switch between single-phase mode and multi-phase mode based on the operating conditions.

Clause 9: The wide-band, multi-phase PLL circuit of any clause herein, wherein each one of the plurality of identical slices of the reconfigurable CPC is configured to be set as active or inactive.

Clause 10: The wide-band, multi-phase PLL circuit of any clause herein, wherein each one of the plurality of identical slices of the reconfigurable CPC is configured to independently adjust an overall charge pump current.

Clause 11: The wide-band, multi-phase PLL circuit of any clause herein, further comprising a loop filter coupled to an output of the PFD-CPC circuit and to a control input of the VCO.

Clause 12: The wide-band, multi-phase PLL circuit of any clause herein, wherein the VCO further comprises a tank circuit.

Clause 13: A method of operating a wide-band, multi-phase phase-locked loop (PLL) circuit, comprising:
selecting an operating mode for a reconfigurable and programmable multi-phase phase frequency detector (PFD) and reconfigurable charge pump controller (CPC) circuit (PFD-CPC circuit) based on one or more defined parameters; wherein the operating mode is a single-phase mode or multi-phase mode, and the PFD-CPC circuit includes a multi-phase PFD and a plurality of identical slices of the reconfigurable CPC and configured to operate in either the single-phase or the multi-phase mode to reduce phase noise and jitter contribution of one or more forward path loop components within a targeted frequency band;
providing a high-frequency reference signal to the PFD-CPC circuit coupled to an output of the divider circuit and a voltage-controlled oscillator (VCO);
maximizing bandwidth and suppressing phase noise and jitter contribution from one or more forward path loop components within a targeted frequency band based on the operating mode.

Clause 14: The method of any clause herein, further comprising generating the high-frequency reference signal using a voltage-controlled oscillator (VCO) coupled to the PFD-CPC circuit and providing the generated high-frequency reference signal to the PFD-CPC circuit.

Clause 15: The method of any clause herein, further comprising providing an output signal from a voltage-controlled oscillator (VCO) coupled to the PFD-CPC circuit, wherein the output signal is used as a feedback signal in conjunction with the high-frequency reference signal to the PFD-CPC circuit for adjusting the operating mode and optimizing noise suppression within the targeted frequency band.

Clause 16: The method of any clause herein, further comprising adjusting a control input of the voltage-controlled oscillator (VCO) coupled to the PFD-CPC circuit based on feedback from a divider circuit to maintain stable operation and accurate tracking of frequency and phase.

Clause 17: The method of any clause herein, further comprising adjusting frequency margining of an output signal from the voltage-controlled oscillator (VCO) to expand the range of operating frequencies within the targeted frequency band.

Clause 18: The method of any clause herein, further comprising adjusting an overall charge pump current of the reconfigurable charge pump controller (CPC) circuit for bandwidth tuning within the targeted frequency band.

Clause 19: The method of any clause herein, further comprising adjusting phase differences between the feedback signal and the high-frequency reference signal within the multi-phase phase frequency detector (PFD) of the PFD-CPC circuit.

While the flowcharts presented for this technology may imply a specific order of execution, the order of execution may differ from what is illustrated. For example, the order of two more blocks may be rearranged relative to the order shown. Further, two or more blocks shown in succession may be executed in parallel or with partial parallelization. In some configurations, one or more blocks shown in the flow chart may be omitted or skipped. Any number of counters, state variables, warning semaphores, or messages might be added to the logical flow for purposes of enhanced utility, accounting, performance, measurement, troubleshooting or for similar reasons.

Some of the functional units described in this specification have been labeled as modules, in order to more particularly emphasize their implementation independence. For example, a module may be implemented as a hardware circuit comprising custom VLSI circuits or gate arrays, off-the-shelf semiconductors such as logic chips, transistors, or other discrete components. A module may also be implemented in programmable hardware devices such as field programmable gate arrays, programmable array logic, programmable logic devices or the like.

Modules may also be implemented in software for execution by various types of processors. An identified module of executable code may, for instance, comprise one or more blocks of computer instructions, which may be organized as an object, procedure, or function. Nevertheless, the executables of an identified module need not be physically located together, but may comprise disparate instructions stored in different locations which comprise the module and achieve the stated purpose for the module when joined logically together.

Indeed, a module of executable code may be a single instruction, or many instructions and may even be distributed over several different code segments, among different programs and across several memory devices. Similarly, operational data may be identified and illustrated herein within modules and may be embodied in any suitable form and organized within any suitable type of data structure. The operational data may be collected as a single data set, or may be distributed over different locations including over different storage devices. The modules may be passive or active, including agents operable to perform desired functions.

The technology described here may also be stored on a computer readable storage medium that includes volatile and non-volatile, removable and non-removable media implemented with any technology for the storage of information such as computer readable instructions, data structures, program modules, or other data. Computer readable storage media include, but is not limited to, a non-transitory machine readable storage medium, such as RAM, ROM, EEPROM, flash memory or other memory technology, CD-ROM, digital versatile disks (DVD) or other optical storage, magnetic cassettes, magnetic tapes, magnetic disk storage or other magnetic storage devices, or any other computer storage medium which may be used to store the desired information and described technology.

The devices described herein may also contain communication connections or networking apparatus and networking connections that allow the devices to communicate with other devices. Communication connections are an example of communication media. Communication media typically embodies computer readable instructions, data structures, program modules and other data in a modulated data signal such as a carrier wave or other transport mechanism and includes any information delivery media. A “modulated data signal” means a signal that has one or more of its characteristics set or changed in such a manner as to encode information in the signal. By way of example and not limitation, communication media includes wired media such as a wired network or direct-wired connection and wireless media such as acoustic, radio frequency, infrared and other wireless media. The term computer readable media as used herein includes communication media.

Reference was made to the examples illustrated in the drawings and specific language was used herein to describe the same. It will nevertheless be understood that no limitation of the scope of the technology is thereby intended. Alterations and further modifications of the features illustrated herein and additional applications of the examples as illustrated herein are to be considered within the scope of the description.

Furthermore, the described features, structures, or characteristics may be combined in any suitable manner in one or more examples. In the preceding description, numerous specific details were provided, such as examples of various configurations to provide a thorough understanding of examples of the described technology. It will be recognized, however, that the technology may be practiced without one or more of the specific details, or with other methods, components, devices, etc. In other instances, well-known structures or operations are not shown or described in detail to avoid obscuring aspects of the technology.

Although the subject matter has been described in language specific to structural features and/or operations, it is to be understood that the subject matter defined in the appended claims is not necessarily limited to the specific features and operations described above. Rather, the specific features and acts described above are disclosed as example forms of implementing the claims. Numerous modifications and alternative arrangements may be devised without departing from the spirit and scope of the described technology.

What is claimed is:

1. A wide-band, multi-phase phase-locked loop (PLL) circuit comprising:
a voltage-controlled oscillator (VCO) having an output;
a divider circuit coupled to the output of the VCO; and
a reconfigurable and programmable multi-phase phase frequency detector (PFD) and reconfigurable charge pump controller (CPC) circuit (PFD-CPC circuit) coupled to the output of the divider circuit, wherein the PFD-CPC circuit includes a multi-phase PFD and a plurality of identical slices of the reconfigurable CPC and configured to operate in either single-phase or multi-phase mode to reduce phase noise and jitter contribution of one or more forward path loop components within a targeted frequency band.

2. The wide-band, multi-phase PLL circuit of claim 1, further comprising a loop filter coupled to an output of the PFD-CPC circuit and to a control input of the VCO.

3. The wide-band, multi-phase PLL circuit of claim 1, wherein the VCO is a low phase noise voltage-controlled oscillator with a split capacitor bank and varactor.

4. The wide-band, multi-phase PLL circuit of claim 1, further comprising a high-frequency reference signal coupled to the PFD-CPC circuit.

5. The wide-band, multi-phase PLL circuit of claim 1, wherein each of the plurality of identical slices of the reconfigurable CPC of the PFD-CPC circuit is configured to independently adjust an overall charge pump current for bandwidth tuning.

6. The wide-band, multi-phase PLL circuit of claim 1, wherein each of the plurality of identical slices of the reconfigurable CPC of the PFD-CPC circuit is configured to adjust frequency margining of an output signal to expand a range of operating frequencies.

7. The wide-band, multi-phase PLL circuit of claim 1, wherein the multi-phase PFD of the PFD-CPC circuit is configured to adjust phase differences between a feedback signal and a reference signal for tracking frequency and phase of an output signal.

8. The wide-band, multi-phase PLL circuit of claim 1, wherein the PFD-CPC circuit is configured to dynamically switch between single-phase mode and multi-phase mode based on operating conditions.

9. The wide-band, multi-phase PLL circuit of claim 1, wherein each one of the plurality of identical slices of the reconfigurable CPC is configured to be set as active or inactive.

10. The wide-band, multi-phase PLL circuit of claim 1, wherein each one of the plurality of identical slices of the reconfigurable CPC is configured to independently adjust an overall charge pump current.

11. The wide-band, multi-phase PLL circuit of claim 1, further comprising a loop filter coupled to an output of the PFD-CPC circuit and to a control input of the VCO.

12. The wide-band, multi-phase PLL circuit of claim 1, wherein the VCO further comprises a tank circuit.

13. A method of operating a wide-band, multi-phase phase-locked loop (PLL) circuit, comprising:
selecting an operating mode for a reconfigurable and programmable multi-phase phase frequency detector (PFD) and reconfigurable charge pump controller (CPC) circuit (PFD-CPC circuit) based on one or more defined parameters; wherein the operating mode is a single-phase mode or multi-phase mode, and the PFD-CPC circuit includes a multi-phase PFD and a plurality of identical slices of the reconfigurable CPC and configured to operate in either the single-phase or the multi-phase mode to reduce phase noise and jitter contribution of one or more forward path loop components within a targeted frequency band;
providing a high-frequency reference signal to the PFD-CPC circuit coupled to an output of a divider circuit and a voltage-controlled oscillator (VCO); and
maximizing bandwidth and suppressing phase noise and jitter contribution from one or more forward path loop components within a targeted frequency band based on the operating mode.

14. The method of claim 13, further comprising generating the high-frequency reference signal using a voltage-controlled oscillator (VCO) coupled to the PFD-CPC circuit and providing the generated high-frequency reference signal to the PFD-CPC circuit.

15. The method of claim 13, further comprising providing an output signal from a voltage-controlled oscillator (VCO) coupled to the PFD-CPC circuit, wherein the output signal is used as a feedback signal in conjunction with the high-frequency reference signal to the PFD-CPC circuit for adjusting the operating mode and optimizing noise suppression within the targeted frequency band.

16. The method of claim 13, further comprising adjusting a control input of the voltage-controlled oscillator (VCO) coupled to the PFD-CPC circuit based on feedback from a divider circuit to maintain stable operation and accurate tracking of frequency and phase.

17. The method of claim 13, further comprising adjusting frequency margining of an output signal from the voltage-controlled oscillator (VCO) to expand a range of operating frequencies within the targeted frequency band.

18. The method of claim 17, further comprising adjusting an overall charge pump current of the reconfigurable charge pump controller (CPC) circuit for bandwidth tuning within the targeted frequency band.

19. The method of claim 15, further comprising adjusting phase differences between the feedback signal and the high-frequency reference signal within the multi-phase phase frequency detector (PFD) of the PFD-CPC circuit.
